(19) United States
(12) Patent Application Publication
(10) Pub. No.: US 2007/0019687 A1
(43) Pub. Date: Jan. 25, 2007

(54) Technique for converting bit rates

(75) Inventors: Jacob Ruthstein, Petach Tikva (IL); Lev Litinsky, Bat-Yam (IL); Amihal Viks, Ramat Gan (IL)

Correspondence Address: BROWDY AND NEIMARK, P.L.L.C.;624 NINTH STREET, NW, SUITE 300, WASHINGTON, DC, 20001-5303, US

(73) Assignee: ECI Telecom Ltd., Petach Tikva (IL)

(21) Appl. No.: 11/448,151

(22) Filed: Jun. 7, 2006

Related U.S. Application Data
(63) Continuation-in-part of application No. 10/445,993, filed on May 28, 2003.

(30) Foreign Application Priority Data
Jun. 4, 2002 (IL) 150011
Jun. 8, 2005 (IL) 169071

(51) Int. Cl. H04J 3/02

(52) U.S. Cl. 370/537

(57) ABSTRACT

A binary tree-like structure for converting bit rates in a telecommunication system, comprising at least one cyclic generator (CG) adapted to present a higher bit rate called R1 substantially as a sum of two lower bit rates called R2 and R3 by cyclically producing, per n clocks of the bit rate R1, m first type signals as clocks of the bit rate R2 and (n−m) second type signals as clocks of the bit rate R3, where m and n are parameters of the CG and integers such, that m<n. The two lower bit rates R2 and R3, based on its parameters m and n, can be presented as follows: R2=mR1/n, R3=(n−m)R1/n. The higher bit rate R1 of a particular CG is either obtained from outside of the binary tree-like structure or constitutes a lower bit rate of another, upper range CG of the structure, while each of the lower bit rates R2 or R3 of a particular CG is either dispatched away from the structure or constitutes a higher bit rate of another, lower range CG of the structure.

The present patent application is a Continuation-In-Part of the U.S. patent application Ser. No. 10/445,993 filed on 28 of May 2003 as a national phase of a PCT application claiming priority of Jun. 4, 2002 from IL patent application 150011. Additionally, this CIP application claims priority from IL patent application 169071 filed Jun. 8, 2005.

### Field of the invention

The present invention relates to a technique for converting bitorates, in particular, to methods and devices for providing bit rates conversion with low jitter and for multiplexing a number of data streams having different bit rates into a common data stream using the proposed ways of conversion.

### BACKGROUND OF THE INVENTION

Converting a lower bit rate data stream incoming a converter, into a higher bit rate data stream outgoing the converter, is usually provided by inserting between binary words of the incoming lower rate data stream so-called “silent” binary words which fill extra positions not carrying information in the outgoing higher rate data stream. The “silent” portions are usually provided by temporary disabling transmission of information bits of the incoming data stream.

The presence of such “silent” positions in the real data create a so-called jitter effect which shows itself as sharp undesired changes in the frequency and amplitude of the “netto” information when filtered from the outgoing signal. Long and unequal time distances between the “silent” positions in the outgoing data stream degrade the quality of transmission.

U.S. Pat. No. 6,226,661 teaches one method of obtaining distributed jitter in sample rate conversion, and describes a technique of converting bit rates using binary ratios to express bit rates relation. The method requires complex calculations and compensation of phase differences introduced by the converter.

To the best of the Applicant's knowledge, no simple practical solutions are described in the prior art to obtain low jitter bit rate conversions, which would enable conversion of any bit rate to a required one by easy adjusting the converter.

Also, no methods are described, which would propose a low jitter mapping of a low bit rate data stream into a high bit rate data stream.

In modem communication systems, there is always a problem of judicious bandwidth allocation for a number of data streams. This task can be defined as a task of optimally dividing a total given bit rate between a number of data streams to be further transmitted via a communication line (preferably, in a multiplexed form).

There is yet a further task of multiplexing a number of data streams, having various bit rates, with a minimal possible jitter in the multiplexed stream.

US 6,570,849 describes a method of transmitting interleaved real-time and non-real-time data on a packet based network so as to provide voice Quality of Service comparable to the Time Division Multiplexing realm of traditional telephony. The method reduces packet jitter and delay by employing separate queues for the different types of data as well as through the use of jitter buffers. The interleaving method consists of a number of discrete concepts and mechanisms, that, when used together, provides consistent high-quality transmission of real-time data over packet/frame/cell-based networks. The elements required for this method include time-slot co-ordination, a dynamic MTU algorithm, and a Multiple queue egress traffic management system.

The above-mentioned technology suffers from complexity both of the method and of the implementation.

### OBJECT OF THE INVENTION

It is therefore an object of the present invention to provide a simple technique of generation first type/second type (enabling/disabling) signals in a manner ensuring presenting a higher bit rate as a sum of lower bit rates, for example for low jitter transmission of an incoming lower rate data stream over an outgoing higher rate data stream.

It is an additional object of the invention to apply such a simple technique of generating two types of signals for presenting a higher bit rate as a sum of two or more lower bit rates, for example for allocating bandwidth of a given total bit rate to a number of data streams having different lower bit rates.

### SUMMARY OF THE INVENTION

To achieve the above objects, and according to one aspect of the invention, there is provided a binary tree-like structure for converting bit rates in a telecommunication system and comprising at least one cyclic generator (CG), wherein each particular CG is adapted to present a higher bit rate called R1 substantially as a sum of two lower bit rates called R2 and R3 by cyclically producing, per n clocks of the bit rate R1, m first type signals as clocks of the bit rate R2 and (n−m) second type signals as clocks of the bit rate R3, where m and n are parameters of said CG and integers, m<n; so that said two lower bit rates R2 and R3 are presented as follows, based on the parameters m and n: R2=mR1/n, R3=(n−m)R1/n; and

wherein the higher bit rate R1 of a particular CG is either obtained from outside of said structure or constitutes a lower bit rate of another, upper range CG of the structure, while each of the lower bit rates R2 or R3 of a particular CG is either dispatched away from the structure or constitutes a higher bit rate of another, lower range CG of the structure.

The above-described binary tree-like structure can be used for bandwidth allocation in a telecommunication system, such a structure being capable of allocating component bit rates by dividing a given total bit rate called X1 into two or more component bit rates called X2, . . . , XN being respectively equal or more than required bit rates called x1, . . . , xN, i.e., (X2≧x2 . . . , XN≧xN) so that

the total bit rate is equal to the sum of component bit rates (X1=X2+. . . XN ≧x2+ . . . +xN),

said structure dividing the total bit rate X1 into a plurality of component bit rates X2, . . . , XN according to a binary tree algorithm, so that said total bit rate X1 is fed to one CG of the structure as the higher bit rate of said CG, and each of the component bit rates X2, . . . , XN is received as a lower bit rate of either of said CG or another CG of the structure,

wherein each of the Cyclic Generators divides its higher bit rate R1 into its two lower bit rates R2 and R3, based on its parameters m and n as follows:
R2=R1/n, R3=(n−m)R1n.

In the above definitions, the term “bit rate” can be understood to be equal or proportional to the rate of clock pulses for a corresponding data stream.

According to a second aspect of the invention, there is proposed a cyclic generator (CG) for converting bit rates, capable of generating first type signals and second type signals, the generator being adapted to present a first bit rate R1 substantially as a sum of a second bit rate R2 and a third bit rate R3,

wherein:
R2=mR1/n,

m<n,

m and n are integers and parameters of said generator, and

wherein:

the CG is capable of generating m of said first type signals and (m−n) of said second type signals per n clocks of the bit rate R1, while substantially uniformly distributing said m signals among said (n−m) signals,

said m signals serving as m clocks of the bit rate R2, while said (n−n) signals serving as (n−m) clocks of the bit rate R3.

It should be noted that the second type signal can be either a pre-selected signal different from the first type signal, or (possibly) just absence of the first type signal in the predetermined timing.

In the most preferred embodiment, the CG, to ensure the above requirement, has a number of changeable internal states ≦n and is capable of generating first type/second type signals according to the following rules:
a) selecting an initial state S of the generator, S≦n;
b) at a clock of bit rate R1, obtaining a current state of the generator S′=S+m;
c) if S′≧n, generating a first type signal, and replacing the current state S′with (S′−n);
if S′<n, generating a second type signal, without changing the current state S′,
d) at the next clock of the bit rate R1, repeating from step b, while using the current state as a new initial state.

Mathematically, the above algorithm can be written down as the following two operations, taking place per one clock of the R1 bit rate:
E=(S+m)div n
S=(S+m) mod n

The generator as described above can be used in various case of data transmission.

According to one embodiment, the cyclic generator CG can be called and used as a generator of enabling/disabling signals (EG), wherein the first type signals are enable signals while the second type signals are disable signals.

In view of that, the cyclic generator of enabling/disabling signals (Enable Generator—EG) can be suitable for converting an incoming data stream with a bit rate R2 into an outgoing data stream with a higher bit rate R1, wherein R2≅mR1/n, m<n, m and n—integers, the EG having a number of internal states ≦n and being capable of generating periodic enabling/disabling output signals such that the disable signals are optimally distributed among the enable signals.

In this embodiment, the bit rate R3 is the bit rate of disable signals (or stuffing signals, as will be described further below in connection with mapping of the data stream having a lower bit rate into the data stream having a higher bit rate).

The integers m and n are the EG parameters selected so as to provide m enable signals for n clocks of the bit rate R1. The meaning “clocks” is to be understood herein as time intervals between periodic, accurately spaced synchronization signals serving a particular bit rate. Depending on a particular implementation, one or more bits of information can be transmitted per one clock (said time interval).

It should be mentioned, however, that sometimes in the specification the term “clock” is used in the meaning of a synchronization frequency proportional to a particular bit rate.

It will further be shown that the parameters m, n can also be adjustable to maintain stable, error free bit rate conversion.

In other words, the EG disable signals occur between the EG enable signals with a minimal periodicity, so that the single disable signals are almost uniformly distributed between the enable ones.

As has been noted before, the disable signal (the second type signal) can be either a preselected signal different from the enable signal (the first type signal), or just an absence of the enable signal in the predetermined timing.

A simple idea of selecting m and n parameters of the EG to convert an incoming data stream having a bit rate R2 to an outgoing data stream having a bit rate R1 allows using one common internal bit rate (clock) R2 in a chip handling at its inputs a number of incoming data streams with respective different bit rates R2′, R2″ . . . and outputting one or more outgoing data streams respectively having these same bit rates R2′, R″ . . . or bit rates derived therefrom (say, multiples thereof). To implement this idea, at least at the inputs of the chip, respective differently adjusted EG generators are provided each cooperating with a FIFO, to convert the incoming data streams′bit rates into the common internal bit rate R1, so that the core of the chip operates at said common internal bit rate R1.

For example, a chip of this type may be required for implementing such network elements as regenerators, transponders, or the like.

Preferably, a particular input FIFO can be used for storing data inputted at the bit rate (clock) R2, the corresponding EG can be used for creating enable-disable signals which are used a) for reading the FIFO at the clock R1 thus creating an internal data stream at the clock R1, and b) for transmitting a corresponding internal stream of the enabling/disabling signals in parallel with the internal data stream. Both these internal streams can be transformed in the chip for handling the particular incoming data stream, and finally utilized at the corresponding output for creating the outgoing data stream at the clock R2 or kR2. The number of outgoing data streams may be unequal to the number of incoming data streams.

The proposed CG (EG) allows defining a method of low jitter mapping, utilizing the low jitter CG, as follows.

A method of low jitter mapping, of an incoming (client's) data stream having a lower bit rate called C, into a data stream having a higher bit rate called H, and using stuffing signals with a bit rate called ST, by utilizing the Cyclic Generator (CG) and by representing the bit rate R1 of the CG by the bit rate H, the bit rate R2 of the CG by the bit rate C, and the bit rate R3 of the CG by the bit rate ST, the method ensuring that, statically or dynamically, actual values R1ₜ, R2ₜ, R3ₜ, of the respective bit rates R1, R2, R3 of the CG are bound substantially as follows:
R1ₜ=R2ₜ+R3ₜ,
by fulfilling one of the following conditions:
a) ensuring C/H =const;
b) dynamically adjusting a ratio m/n of the CG to (m/n)ₜ, if C/H≠const.

Indeed, if the ratio C/H =const, then R2/R1 =const, so m/n =const and the low jitter condition is maintained. This situation usually takes place when C and H are independent stable rates, or when one of the rates C, H is a given stable rate and the second one is a derivative there-from. In such cases, R1=R2+R3 just statically. However, if C/H≠const, we need dynamical adjustment of the ratio m/n of the CG to (m/n)ₜ, to dynamically obtain R1ₜ=R2ₜ+R3ₜ. Such dynamic adjustment of the ratio m/n can be performed periodically, for particular periods “t” of transmission.

The low-jitter mapping of the incoming (client's) data stream is usually performed into a succession of data frames of an outgoing data stream having a higher bit rate (H), wherein each of the frames comprises an overhead portion and a payload portion,

The method comprises:

using a first said CG to control filling the payload portion of each data frame of the outgoing data stream with information bits of the incoming data stream diluted with stuffing bits, wherein the filling is performed at the bit rate H, the incoming data stream has the bit rate C, the stuffing bits have the bit rate ST;

using at least one predetermined location in the overhead portion of at least one of said data frames to indicate an internal state of the EG corresponding to a suitable payload portion, for further de-mapping of said portion.

The filling of the payload is performed by inserting the information bits when the EG generates enable signals, and inserting stuffing bits when the EG does not generate enable signals.

The high bit rate outgoing data stream can be, for example, one of standard data streams belonging to well known telecommunication technologies such as SDH, SONET, OTN, PDH.

For example, the predetermined location (S-location) may constitute any non-specified overhead byte in the first frame. The information in such a byte, whenever is read at a receiving site, serves as a de-mapping key, i.e., informs a de-mapper about the internal state of the first EG at which the mapping of the first frame payload was started. Position of the S-location in the overhead may correspond to a particular payload bit, or row of the first frame from which the mapping started. Actually, the state may be transmitted once and be aged up to any random fault distresses the system. After a fault, the state must be refreshed. So, in the absence of faults, the EG internal state may be transmitted only once. However, it may be transmitted each frame, or even several times per one frame if so desired, either for confirming the initial internal state or for updating a current internal state.

In other words, the above-described method of low-jitter mapping is logically followed by de-mapping at a receiving end with the aid of a second EG identical to the first EG, wherein the de-mapping comprises:

adjusting the second EG to have parameters m and n respectively identical to said parameters of the first EG,

obtaining (reading) the internal state of the first EG from said predetermined location of the overhead portion of one of said frames and setting the second EG into the obtained internal state,

using the second EG to read the incoming data stream, from the payload portion corresponding to the internal state, at the bit rate R2 (or C).

As follows from the given definition, the mapping may be a so-called synchronous mapping, when the bit rates R2 and R1 are constant (or their ratio is constant), and when the parameters m and n are respectively constant and known in advance. In other words, m and n are known in advance both at a transmitting side and at the receiver side, and both the first EG and the second EG can be adjusted for the whole transmission session.

In practice, the mapping in real systems is usually performed when the higher bit rate H representing R1 and/or the lower bit rate C representing R2 may slightly change, so for preserving the equation R1=R2+R3 the m/n ratio cannot remain constant. Such mapping will be called asynchronous.

The method of asynchronous mapping preferably comprises: monitoring ratio between the bit rates H and C, (say, by monitoring depth of the FIFO), periodically adjusting the ratio m/n to (m/n)ₜ, in the first Enable Generator (EG) and, for further de-mapping, simultaneously indicating in a predetermined location of the overhead portions of the data frames, information enabling obtaining the adjusted ratio (m/n)ₜ actual for a particular period of transmission.

The above method enables regulating the mapping by using a current (m/n)ₜ, up to a new adjusted ratio (m/n)ₜ is obtained.

To maintain the bit rate R1 constant in conditions when C and/or H drift from their initial values, at least one of the current actual parameters n, m is to be updated thereby adjusting the ratio (m/n)ₜ.

The indication of such an adjustment can be performed by inserting current binary values of m, n in predetermined places of the overhead portion of the data frames of the outgoing data stream at a pre-determined moment of time, for obtaining (m/n)ₜ at the receiving site.

The step of de-mapping at the receiving site, preferably, will further comprise reading the updated parameters m and n from the overhead portion of a frame and adjusting the second EG to the obtained parameters m, n up to receiving newly updated said parameters.

The above-described methods suppose using relatively simple and easily modified means for converting an incoming data stream having an arbitrary bit rate, into a higher bit rate outgoing data stream.

Owing to that, the same concept may be applied for enveloping and transmitting a number of client's data streams via a high rate transport data stream while preserving the advantage of low jitter.

Therefore, a method is further provided for transporting, with a low jitter, “k” incoming data streams having arbitrary bit rates, by “k” SONET/SDH lower order data streams further multiplexed into a SONET/SDH higher order data stream, the method comprising mapping each of said incoming data streams into a corresponding lower order SDH/SONET data stream according to the above-described mapping methods, and multiplexing the obtained “k” lower order SONET/SDH data streams into the higher order transport data stream using a bit-interleaving principle.

There are also proposed suitable systems for low jitter mapping and a system for low jitter data transport that will be described in the detailed description below.

Coming back to the binary tree-like structure, the following features and implementations should be mentioned.

In the binary tree-like structure, the distribution of bit rates (clocks) may include so-called idle or waste bit rates, i.e., one or more of the component bit rates X2, X3, X4, . . . , XN may at least partially comprise waste bit rate. Appearance of waste bit rate(s) is a result of the difference between the required bit rates x2, x3, . . . , xN and the obtained component bit rates X2, X3, X4,. . . , XN.

Judicial distribution of waste bit rates (waste clocks) may essentially lower the resulting jitter.

The waste bit rate(s) can be formed at various ranges of the binary tree, and can be useful both in cases when the allocated component bit rates must comprise spare bandwidth, and in cases where values of one or more of the component bit rates X2, X3, . . . , XN should be exactly equal to the required bit rates x2, x3, . . . , xN. In the latter case, one or more component bit rate being completely waste can be introduced and will represent so-called fictitious client(s).

In the most preferred embodiment of the binary tree-like structure, at least one of the Cyclic Generators is the low jitter CG (i.e., capable of uniformly distributing signals of the first type among signals of the second type). Such a binary tree-like structure is more effective to perform bandwidth allocation suitable for low jitter multiplexing.

There are some features of the binary tree-like structure performing low jitter bit rate allocation. For example, a low jitter tree-like structure is usually arranged so that majority of CG are built so that a particular CG of the majority presents its higher bit rate R1 as a sum of its two lower bit rates R2 and R3, wherein a ratio R2/R3 of said CG is closer to 1, than a ratio between any of the R2 and R3 and a lower bit rate of another CG of the structure.

For example, from a group of component bit rates X2, X3, X4, . . . XN being 2 kbps, 5 kbps, 17 Kbps, 34 Kbps and 58 Kbps, the following “close” pairs of leaf-range outgoing bit rates can be arranged in the structure: 2-5; 17-34; and 58 is alone. A method of building such a structure will be disclosed in the detailed description.

Another feature of a low jitter tree-like structure is such that at least one of the component bit rates maximally differing by value from the remaining component bit rates is separated as one of the lower bit rates of a CG at a higher range (preferably, root-range) of the binary tree-like structure.

According to yet a further aspect of the invention, there is proposed a method of bandwidth allocation in a communication network by utilizing a binary tree-like structure (any of the above-mentioned ones), for dividing a given total bit rate X1 into two or more component bit rates X2, . . . , XN being respectively equal or more than required bit rates x2, . . . , xN of two or more initial data streams.

The method of bandwidth allocation is usually completed by further multiplexing the two or more initial data streams that have respectively obtained the allocated component bit rates X2, . . . , XN, under supervision of said binary tree-like structure, by producing from said structure periodically distributed clocks assigned to different component bit rates. By using the low jitter binary structure, the low jitter multiplexing is achieved.

For further de-multiplexing the resulting data stream, the method preferably comprises providing and transferring, to a remote site, information on status of said binary tree-like structure.

Preferably, the method comprises periodically transmitting the information on status of said binary tree-like structure placed at a transmitting site to an equivalent binary tree-like structure placed at a receiving site, and de-multiplexing the multiplexed said two or more initial data streams under control of the binary tree-like structure placed at the receiving site, by using said information.

The above method of bandwidth allocation (with or without further multiplexing) may comprise mapping of at least one of said initial data streams upon allocating for them the respective component bit rates X2, . . . , XN (but before optional multiplexing thereof), the mapping of a particular initial data stream being performed by providing an additional cyclic generator CG and utilizing it according to the method of claim 6, wherein the higher bit rate RI of the additional CG is represented by the component bit rate X(i) allocated for said particular data stream, and the lower bit rate R2 of the additional CG is represented by the required bit rate x(i) of said particular data stream.

There is also provided a telecommunication system comprising a first assembly including a first binary tree-like structure for bandwidth allocation, and a multiplexer associated with the first binary tree-like structure, the first assembly being capable of judiciously dividing a given total bit rate between a number of initial data streams, correspondingly multiplexing said initial data streams, and producing information about status of the first binary tree-like structure.

If the first tree-like structure is a low jitter one, the system will perform low jitter multiplexing.

The telecommunication system preferably comprises a second assembly comprising a demultiplexer associated with a second binary tree-like structure equivalent to said first structure, said first assembly being in communication with said second assembly for transmitting data and information about status of the first binary tree-like structure; the second assembly, using said information, being capable of de-multiplexing the initial data streams upon being multiplexed by said first assembly.

The telecommunication system may comprise the binary structure and at least one additional cyclic generator CG (or EG) for mapping at least one of said initial data streams, said at least one additional CG being associated with said binary three-like structure so that one of the component bit rates X2, . . . , XN obtained in the structure is used as the higher bit rate R1 of the additional CG, and a corresponding one of the required bit rates x2, . . . , xN is used as a lower bit rate R2 of the additional CG, the system thereby enabling conversion of at least one lower required bit rate into a higher allocated component bit rate. If the system also comprises a multiplexer, the higher component bit rates can be further multiplexed.

### BRIEF DESCRIPTION OF THE DRAWINGS

FIG. 1a is a diagram schematically illustrating the principle of the proposed cyclic generator CG of two types of signals (in a particular case, generator of enable/disable signals (EG).

FIG. 1b is a flow-chart of the CG.

FIG. 1c is an exemplary table illustrating transitions between internal states of the EG, and output (enabling) signals.

FIG. 2 is a block-diagram of a system schematically illustrating a synchronous mapping/de-mapping principle using the proposed CG.

FIG. 3 is a modified diagram showing how asynchronous mapping can be implemented.

FIG. 4 is a schematic block diagram illustrating the transmission of a number of incoming data streams using one transport data stream and the above-described mapping/de-mapping principle.

FIG. 5 is a schematic block diagram illustrating a system handling a number of incoming and outgoing streams having different clocks, while utilizing a common internal clock inside the system. FIG. 6A illustrates a schematic principle of allocating bandwidth of a data stream having the total bit rate X1 for a number of data streams with bit rates x2, x3 . . . , xN, or a principle of dividing a given total bit rate X1 into a number of lower bit rates X2, X3 . . ., XN, wherein X1>x2+x3+ . . . xN.

FIG. 6B is a symbolic illustration of a tree-like structure of Cyclic Generators (CG) according to the invention.

FIG. 6C schematically illustrates how a tree-like structure of Cyclic Generators (CG) can be built according to one binary tree algorithm proposed for bandwidth allocation.

FIG. 6D schematically illustrates how another tree-like structure of Cyclic Generators (CG) can be built according to another binary tree algorithm proposed for bandwidth allocation.

FIG. 6E is a specific numeric example of constructing a tree-like structure of cyclic generators, to illustrate one of the proposed methods of bit rate conversion (or bandwidth allocation).

FIG. 7 shows an embodiment of a telecommunication system differing from the system illustrated in FIG. 4 in that it performs bandwidth allocation between a number of different data streams, which are further mapped onto different obtained component bandwidths to be further multiplexed in a common data stream having a total given bandwidth.

### DETAILED DESCRIPTION OF THE INVENTION

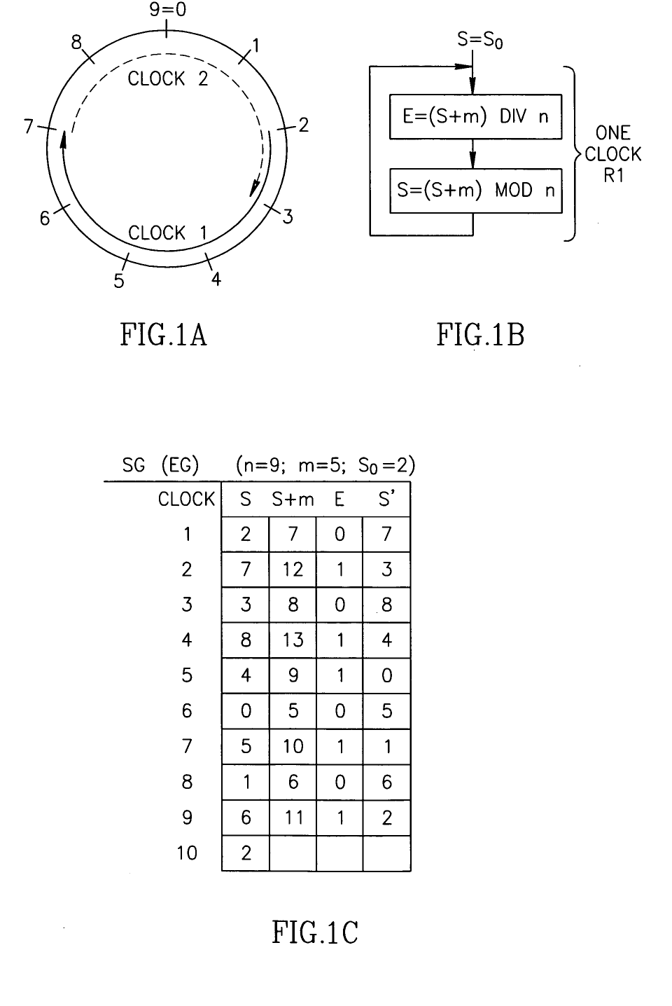

FIG. 1a schematically illustrates a circular diagram of the proposed cyclic generator CG; let in this particular case it is an enable generator (EG). The function of the EG is to generate enable/disable signals, say for reading data incoming a FIFO with a constant arbitrary client bit rate R2, at another (higher) bit rate R1−for example, to allow further transmission of this data with this another bit rate R1. In the enable generator, R2 =mR1 /n ( R1, for example, is any selected SDH rate), wherein both m and n are integers and m<n. The meaning of the ratio is that for each n clocks of the enable generator EG (i.e., for each n clocks of R1) there will be m clocks with enabling signals to transform the bit rate R2 into bit rate R1.

FIG. 1a illustrates the diagram for an exemplary case where n=9, m=5 To begin its operation, the generator EG defines an initial state (condition) S within a cycle being n clocks, at each clock the generator changes the state so that S′=S+m, and acts as follows:

if S′≧n, a bit from the incoming data is transmitted (ENABLED), and the condition S′replaced by S′−n =S+m−n;

if S′<n, no bit of the incoming data is transmitted (DISABLED), and the condition S′remains the same.

The mathematically written algorithm is illustrated in FIG. 1b, and is performed by the EG at each clock of R1 bit rate:
E=(S+m) div n,
S′=(S+m) mod n.
Let S=2. In the table, shown in FIG. 1c, one may see that the disabling signals are maximally uniformly distributed among the enabling ones. It should be noted that the EG of this particular example has nine different internal states, i.e., as many as the number “n” of clocks. However, the number of different internal states may be less than “n” , i.e., the EG may not pass some specific states.

How the numbers m and n are selected in real schemes? Naturally, the ratio of real bit rates R2/R1 can be obtained since the real bit rates are known. According to the above equation, R2/R1 =m/n. If one of the parameters (say, n) is selected, the other parameter m, with a particular accuracy, can be found as m =(R2/R1)n. In real EG schemes, n can be selected to be 10⁶ or even more, the values n and m are preferably held in binary registers (the structure of EG is not shown).

Accuracy of the proposed EG can be set in advance by selecting the length of binary registers assigned for the parameters “m” and “n” . For example, registers of 20 bits enable representing numbers in the order of millions, and allow converting bit rates differing in small values with a mistake close to +0.5 single PPM values (i.e., values expressing bit rate changes of 0 to 0.5 Pulses Per Million). For example, the PPM required for bit rates in SDH networks should not exceed ±4.6 PPM. Therefore, the mentioned length of the EG registers is sufficiently accurate for SDH applications.

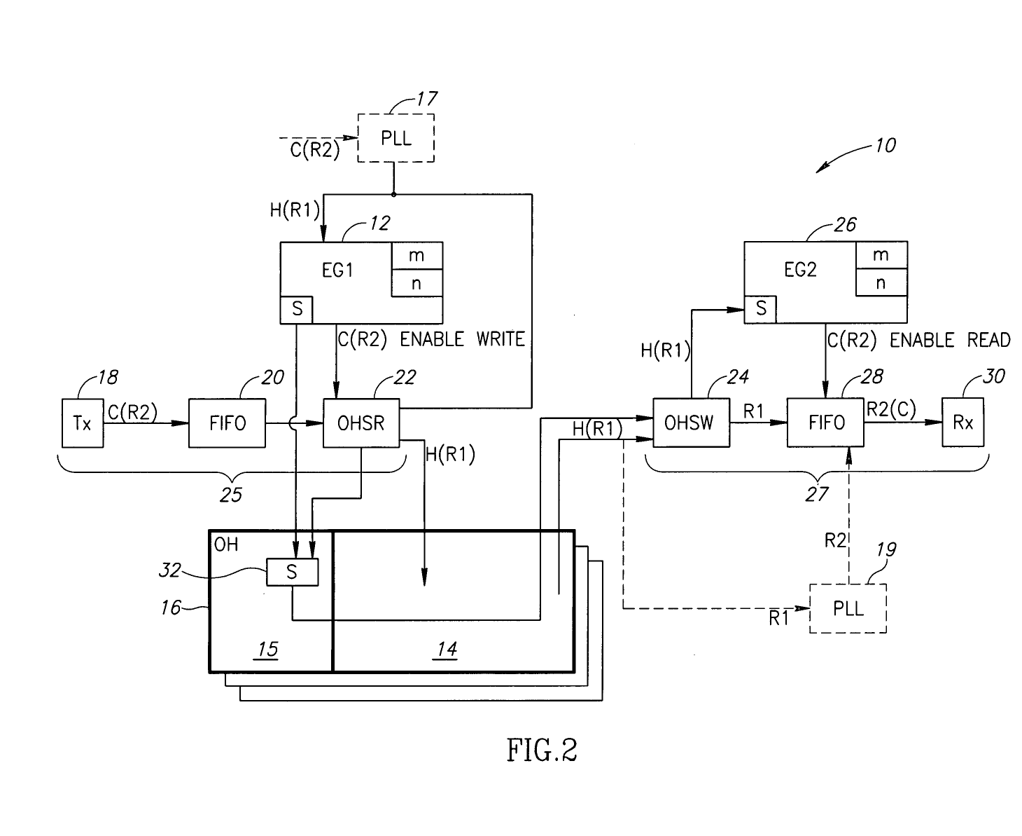

FIG. 2 schematically illustrates a system 10 where a first enable generator EG1 marked 12 is used for mapping a client's data stream having a constant bit rate C (representing the generator's bit rate R2) into informational payloads 14 of frames 16 in a data stream having a higher bit rate H (representing the generator's bit rate R1). The frames 16 (for example, SDH frames each comprising a payload portion 14 and an overhead portion 15) are transmitted from a transmitter site 25 to a receiver site 27. The transmitter site comprises a transmitter Rx 18, a FIFO 20, EG1 12 and a circuit 22 which will be called an overhead synchronized reader (OHSR). The receiver site 27 symmetrically comprises an overhead synchronized writer OHSW 24, a second enable generator EG2 marked 26, a FIFO 28 and a receiver 30.

Enable generators 12 and 26 are identical. FIG. 2 illustrates a version of synchronous mapping, i.e., such where the bit rates C (R2), H (R1), their ratio, and therefore the parameters m, n themselves, and the ratio m/n are preset and constant. The generators 12 and 26 are preliminarily adjusted to the required ratio between the bit rates R2 and R1, by setting registers m and n therein. Such a mapping can be utilized when the R1 and R2 are synchronized in advance, for example created by one and the same source, say R1 is created by a PLL circuit 17 from R2. By using the enable generator 12 capable of uniformly diluting enable signals with disable signals, the mapping can be provided with a very low and, most important, distributed jitter. Exact algorithm of the CG (EG) may vary. The frame 16 is formed from the data stored in the FIFO 20 by combined action of the EGI and OHSR. The function of OHSR is to distinguish between the overhead and payload portions of the frame and to ensure insertion of an initial state S of the EGI in a predetermined location 32 of the overhead 15. Further, when the OHSR declares a payload zone and the EG1 gives an enable write signal, the payload 14 will be filled by data from the FIFO periodically stuffed at those positions which correspond to disable signals of the EG1. By doing this, the distributed stuffing is provided, which results in the controlled distributed jitter.

To enable further de-mapping data from the frame 16 and the following frames, and re-conversion thereof into the bit rate R2, indication of the S corresponding to the mapping pattern should be found in at least one of the frames arriving to the receiving site. This indication is allocated by OHSW, forwarded to the EG2 (26) and stored in it, so as to ensure that EG2 will start operating beginning from the state S. The payload portion of the frame 16 is detected by the OHSW 24 and written into FIFO 28 as is, with the rate R1. The EG2 (26) will enable reading only the data “netto” from FIFO 28, since it starts operating from the state S and uses the same values of the m, n parameters. The data “netto” without stuffing will therefore be read from the FIFO 28 and transmitted to the receiver 30 with the bit rate R2 (actually, C). Alternatively, the “enable read” signal from EG2 may be sent to OHSW 24, for filling the FIFO 28 with payload bytes at the rate R2. a PLL circuit 19 may supply the FIFO 28 with clocks at rate R2 for reading data from the FIFO.

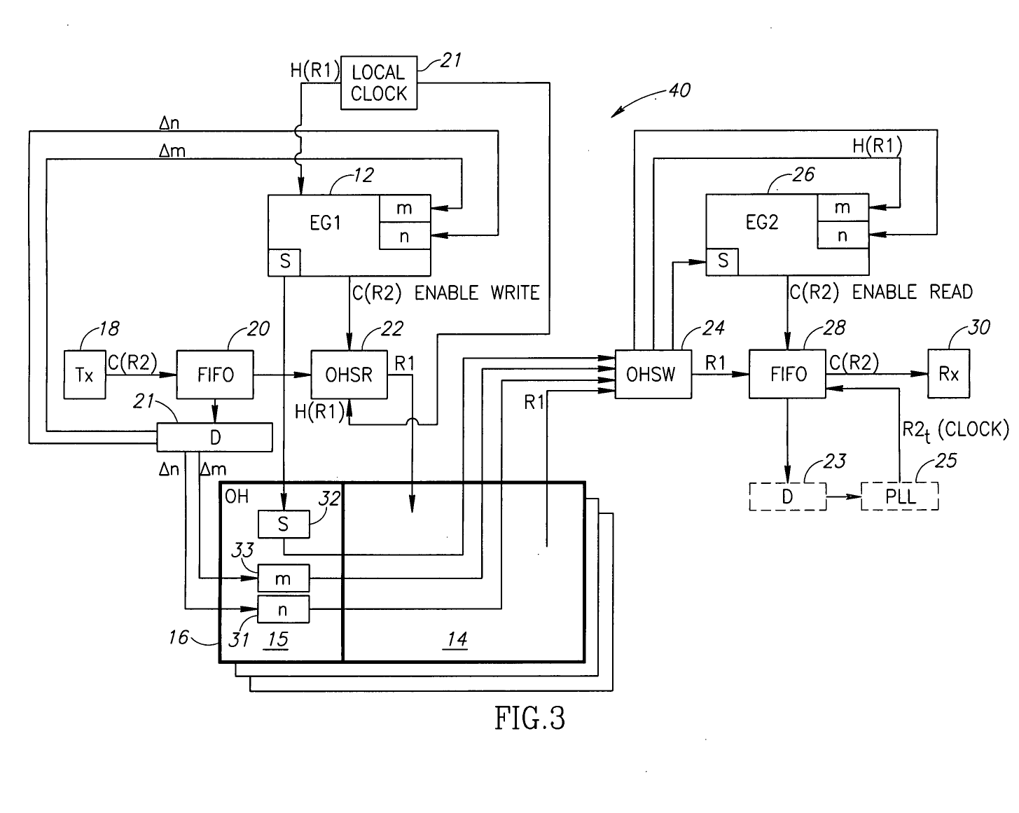

FIG. 3 illustrates a modified system 40 suitable for a case of asynchronous mapping (C/H const, m/n const). Such a mapping can be useful where one or both of the bit rates C, H vary in time, to avoid errors in converting the data. Suppose, that in this case C is produced by a client's transmitter 18, and H—by a local clock 21. However, the bit rates C,H, respectively and dynamically present bit rates R2, R1 of the generator 12 at each period “t” of transmission. When the real ratio between the bit rates C,H changes, FIFO 20 may suffer from the following two critical conditions. A critical condition of the approaching overflow of the FIFO would appear if the bit rate C (R2ₜ) increases/ bit rate H (R1ₜ) decreases, and a critical condition of fast emptying of the FIFO occurs from the opposite reasons. These conditions can be detected by a detector D (21) of the FIFO depth.

To overcome this problem without creating errors, the mapping mechanism should be adjusted and therefore it inevitably becomes asynchronous.

The asynchronous mapping suggests adjusting the m/n ratio from time to time, based on monitoring the FIFO condition. By doing this, the output H (R1) bit rate can be maintained constant.

For example, the EG generator 20 may slightly reduce the rate of emptying the FIFO, if the FIFO is close to emptying, so “m” can be reduced. And vise versa. The generator may be adjusted from the point of m from the point of n, or both.

Whenever either of the parameters m, n are updated in a transmitted frame and in the enabling generator at the transmitting site, the de-mapping site should be informed about it, too. It will happen if the receiving site is informed in advance, what are the places in the OH area where the updated information on m, n appears and what is the time to update the enabling generator after that. To do that, the Inventors propose indicating the changed parameter(s) in pre-set locations 31, 33 of the overhead portion of the transmitted data stream. This information enables obtaining the adjusted ratio (m/n)ₜ actual for a particular period of transmission for further de-mapping.

To provide de-mapping at the receiving site, the OHSW 24 should detect the presence of updating information on m and/or n in the pre-set locations 31, 33 of the frame overhead, and forward it to the EG2 (26) together with the information on S in the location 32. The EG2 (26) will therefore be adjusted to de-map the suitable portion of data according to the updated ratio (m/n)ₜ. The EG 12 and EG 26 will work according to the updated conditions up to the ratio is changed due to any new fluctuations in the bit rates C(R2) and/or H(R1). Additionally, the receiving site may comprise a FIFO depth detector D 23 connected to a PLL clock 25, producing updated (R2 t) clocks for reading from FIFO 28.

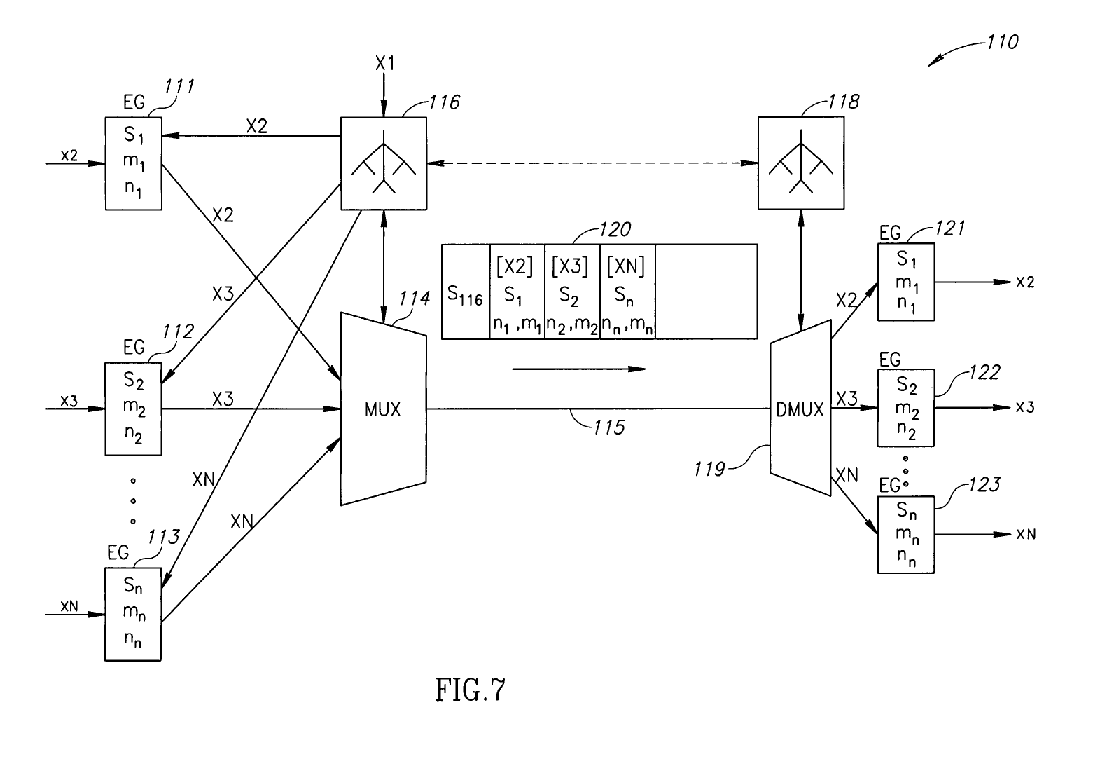

The asynchronous mapping can be used for combined implementations, for example comprising a preliminary stage of bandwidth allocation (one embodiment of a possible combination is illustrated in FIG. 7).

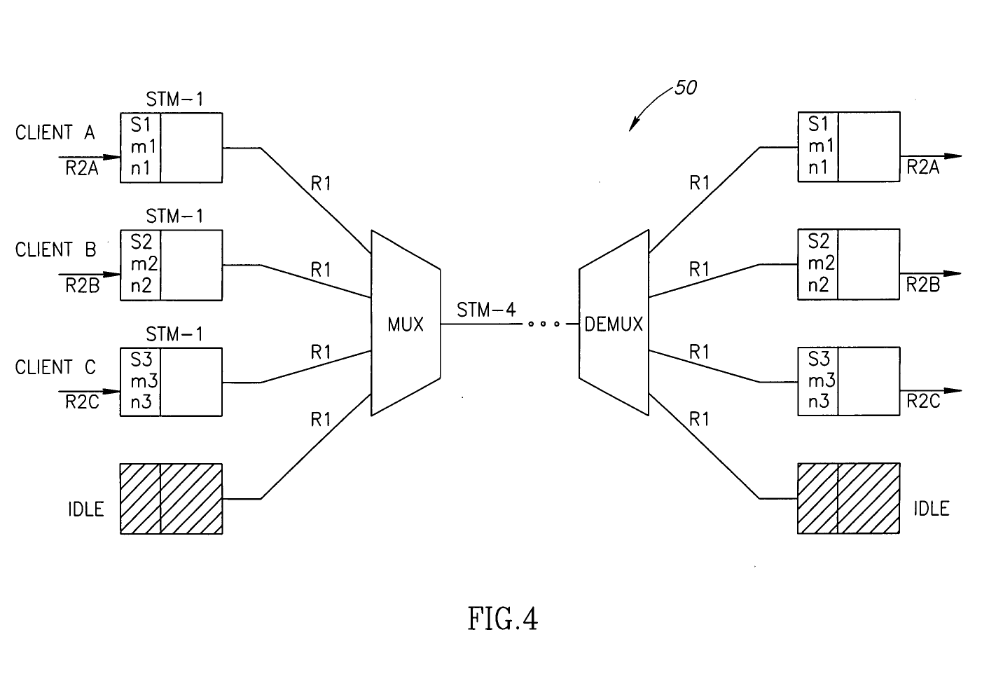

FIG. 4 shows that the mapping principle mentioned above can be used for “packing” a number of arbitrary lower rate data streams into a higher rate data stream, while preserving the advantage of distributed stuffing (and jitter).

In a system 50, three lower rate data streams from clients A, B and C having respective bit rates, which for simplicity will be called R2A, R2B, R2C, are separately mapped into three equal STM-1 SDH data streams (component data streams), each having a standard SDH rate marked R1. For the mapping, each of the three left side parallel branches of the system shown in FIG. 4 is provided with its own EG (not shown) set for its own combination of the parameters m and n, and each converting its lower bit rate R2i into its higher bit rate R1. Each of the STM-1 component data streams carries data supplied by the corresponding lower rate data stream. In this example, every STM-1 frame also carries information S on the state of the corresponding EG and information on the parameters m and n or their change. This information is indicated in predetermined locations of the overhead of the standard STM-1 frame These locations may be different for different data streams R2A, R2B, R2C, but form the point of modularity of the systems they are preferably the same.

Four STM-1 streams may further be multiplexed into one STM-4 high order data stream. Out of the four STM-1 streams, three STM-is respectively comprising the data of R2A, R2B, R2C, will be used. The remaining fourth STM-1 may comprise any data to be transmitted via the same SDH transmitting line with the bit rate R1. In this particular example, this stream is idle, i.e., comprises all stuffing bits.

Owing to the bit-interleaving principle of multiplexing, the information comprised in all four STM-1 streams will be uniformly mixed in the STM-4 data stream and thereby the jitter will remain uniform even in case the fourth (stranger) data stream comprises only stuffing bits.

The obtained STM-4 data stream will be finally de-multiplexed at the receiving site, upon which each relevant STM-1 stream can be de-mapped using information on the suitable S, m, n preserved in the overhead of the STM-1 frames, and utilizing the corresponding EG (not shown) which is to be set according to the received S, m and n.

The advantage of such a mapping is that one may, using a modular and easily adjustable equipment, combine a number of data streams having different non-standard bit rates (R2A, R2B, R2C . . . ) into one higher rate transport data stream.

It should be noted that, according to the invention, not only equal component data streams (like those four having the same bit rate R1) can be handled. An alternative case will be illustrated in FIG. 7.

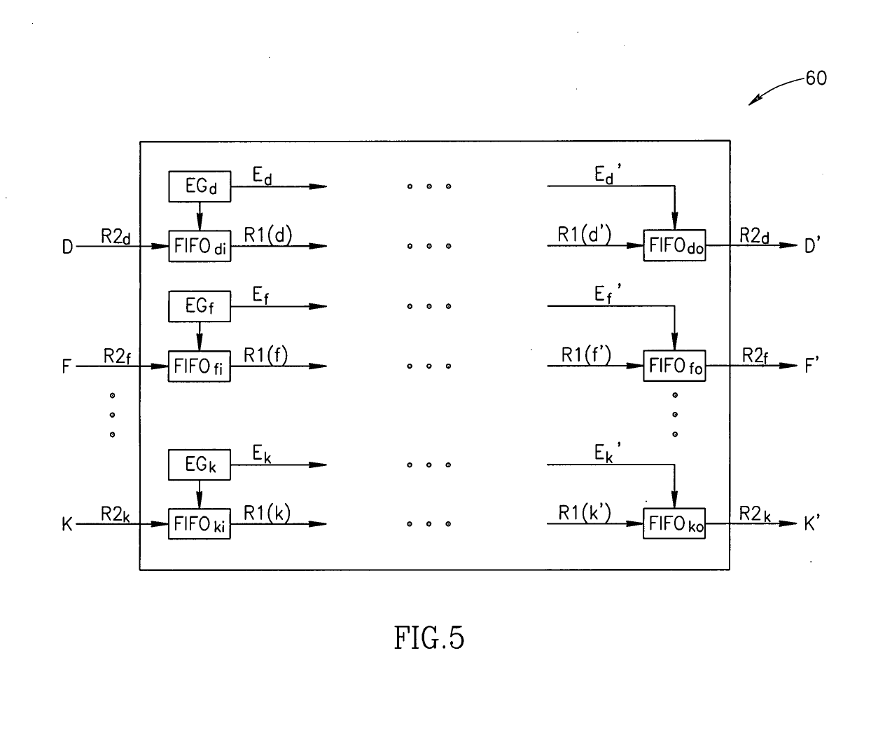

FIG. 5 schematically illustrates a chip 60 intended for handling a number of incoming data streams D, F, . . . , K having different bit rates (clocks) marked for simplicity R2d,R2f, . . . , R2k. In the chip, each of the incoming data streams (say, a stream symbolically called I with the bit rate R2i) is converted, using a corresponding input FIFO(ii) and a corresponding enable generator EG(i)—not shown, into a) an internal data stream having the internal clock R1 carrying data (i) and thus marked R1i and b) an internal stream of enable/disable signals marked E(i). It should be noted that, for maintaining the stable conversion, the FIFO depth can be monitored similarly to the manner illustrated in FIG. 3, and parameters m, n of the enable generator EGi can be adjusted accordingly. In the chip, the mentioned internal streams can be modified owing to handling the incoming data streams: for example, performing for them a FEC (Forward Error Correction) operation, overhead processing, and the like. Such operations may change the internal enable data stream and, consequently, a pattern of the parallel internal data stream. When outputting the processed data stream, the modified internal data stream Ri'can be written into a corresponding output FIFO (io) using its parallel internal enable data stream Ei′. From the FIFO (io), information can be outputted at the initial bit rate (clock) R1i, thus forming the output data stream I′. In this drawing, the outgoing data streams are shown fully symmetric to the incoming data streams, both from the point of the quantity and their output clocks. The system 60 can serve, for example, as a network regenerator for a number of data streams. However, the system (a chip) can be designed to output a number of outgoing data streams non equal to the number of incoming data streams. Moreover, the outgoing data streams may have clocks derived from the clocks of the respective incoming data streams, for example as it takes place in optical transponders.

Between the input (left-side) portion and the output (right-side) portion of the chip 60, external storage means (such as RAM) can be provided to arrange there-inside storage of the data streams R1(i), usually in a multiplexed form. The stored information can be further forwarded from the external storage means (usually, via a demultiplexer) to the output portion of the chip as data streams R1(i′). Alternatively, the input and the output portions of the chip 60 can be connected via an external chain comprising MUX—transmission line—DMUX.

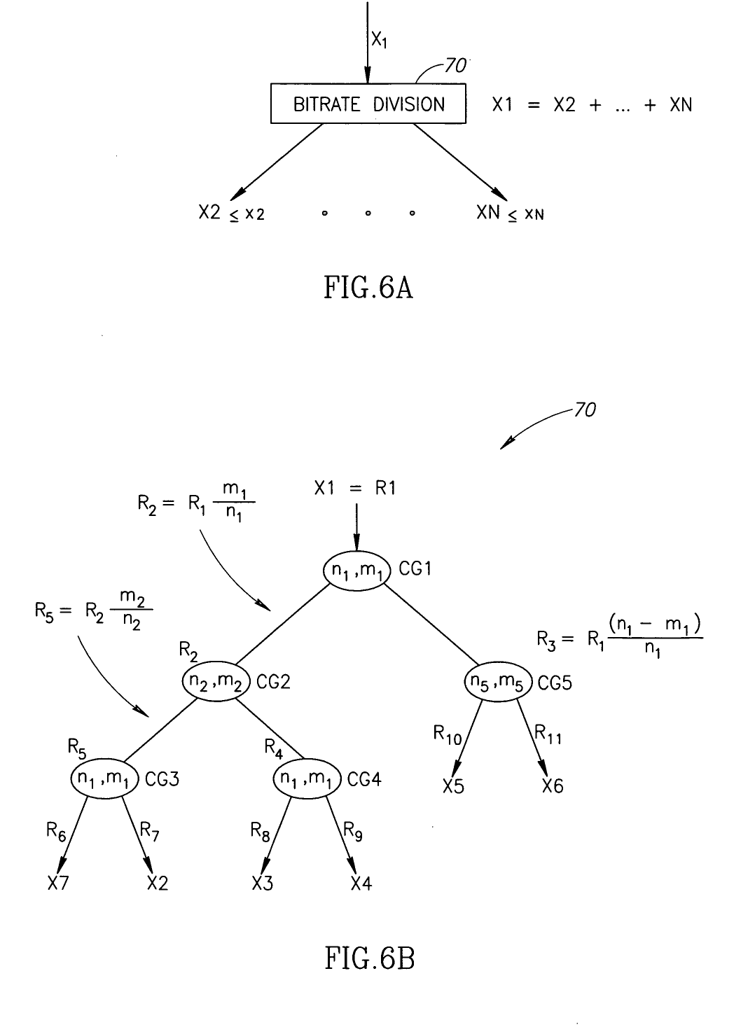

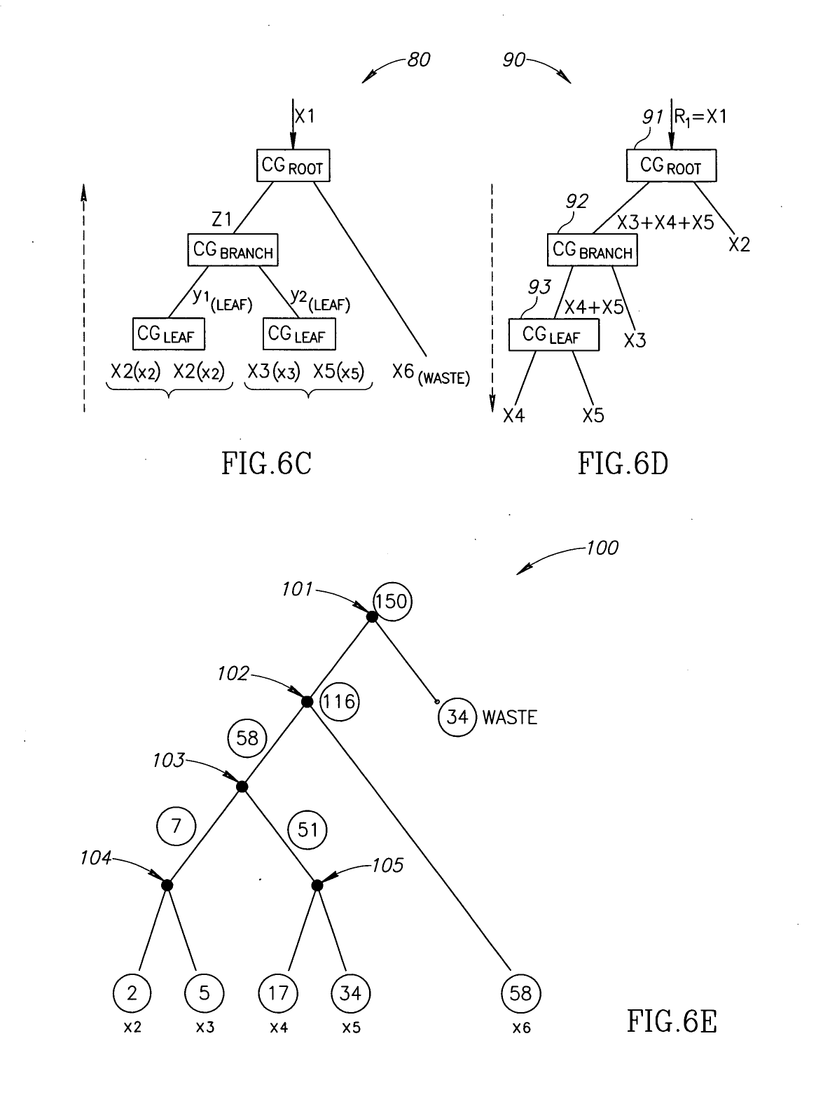

FIG. 6A illustrates a schematic system 70 for allocating bandwidth of a data stream having the total bit rate X1, for a number of lower rate data streams with initial bit rates x2, . . . , xN. The system 70 should divide a given total bit rate X1 into a number of lower component bit rates X2, . . . , XN, wherein X2≧x2, . . . XN≧xN, so that X1 ≧x2+ . . . +xN.

The present invention proposes performing the bit rate conversion by utilizing a binary tree algorithm and a tree-like system of one or more cyclic generators (CG), wherein each of them is capable of dividing a higher bit rate R1 into two lower bit rates R2 and R3, wherein substantially R1=R2+R3. The simplest binary tree structure comprises a single Cyclic Generator of clocks which divides a higher bit rate R1 into two bit rates R2 and R3 so that R1=R1+R3 (equal or approximately equal, depending on specific implementation).

The described binary tree system is most advantageous for bandwidth allocation in telecommunication systems, where data flows with low bit rates might be required to be multiplexed into a higher bit rate data flow, and where a higher bit rate data flow is often split into a number of lower rate data streams.

In one particular and preferable case, the cyclic generator CG of the binary tree structure can be the low jitter CG described above in the summary and the detailed description. FIG. 6B illustrates a schematic implementation of the tree-like system 70, comprising five cyclic generators CG1-CG5. Let the cyclic generators are low jitter ones.

Let the total given bit rate X1 is an incoming bit rate R1 of the cyclic generator CG1 (X1=R1). CG1 is characterized by parameters n1 and m1. According to the definition of the binary tree, and to the algorithm of the cyclic generator with low jitter, two outgoing bit rates R2 and R3 of the CG1 can be obtained substantially as follows:
R2=R1*m1/n1;R3=R1*(n1−m1)/n1;

Usually, these outgoing bit rates R2 and R3 are not yet the required component bit rates Xi, and are to be further divided at a lower range of the tree. For example, CG5 divides the incoming bit rate R3 into two outgoing bit rates R10 and R11, which can be calculated as above, in the analogous manner, taking into account R3 instead of “R1” and the parameters n5 and m5 of the CG5 instead of those of CG1. In this example, R10 and R11 are two component bit rates X5 and X6 respectively. The remaining component bit rates X2, X3, X4, and X7 are received at still a lower range of the tree-like structure, upon dividing R2 by CG2 into R4 and R5, and then dividing R4 and R5 by CG3 and CG4 respectively. Based on the above description and illustration, the Inventors define a method of allocating bandwidths (or component bit rates, say X2, . . . , XN) for two or more data streams respectively having initial bit rates x2, . . . , xN ( where X2≧x2, . . . , XN≧xN) in a common data stream having a given total bandwidth (given total bit rate X1), wherein the total bit rate is equal to or greater than the sum of the initial bit rates of said data streams (X1≧x2+ . . . +xN). The method of bandwidth allocation can be presented as a method of dividing a total bit rate X1 into a plurality of component bit rates X2, . . . , XN according to a binary tree algorithm and using a binary tree-like structure comprising one or more of the above- described CG at one or more ranges of the binary tree structure (wherein said ranges possibly including a leaf-range, a branch range and a root-range), and wherein each of said one or more CGs at any range of the binary tree divides its incoming bit rate into two its outgoing bit rates by assigning the first type signals of said CG to one of its two outgoing bit rates, and assigning the second type signals of the CG to the other of its two outgoing bit rates. Each outgoing bit rate of the CG can be either used for a client (and therefore can be considered terminal), or be further divided by an additional CG of the binary tree structure and be therefore considered an incoming bit rate of said additional CG of the binary tree structure.

It is understood that if the sum of the obtained component bit rates does not exactly equal to the given total bit rate, one or more of the component bit rates at least partially (or wholly) comprises waste bit rate.

There may be a number of methods for constructing the binary tree system, and some of them will be illustrated in the following FIGS. 6C- 6E.

FIG. 6C illustrates one example of the method to build a tree-like system for division bit rates, where clock generators CG are placed at different ranges of a binary tree 80.

One method of building a binary tree system for allocating bandwidth of the total bit rate X1 between more than two clients can be “from the leaf range upwards” , as follows:

1. Combining two clients, i.e., selecting a pair of component bit rates to be obtained and selecting for them a Cyclic Generator CG(leaf) such that allows obtaining the two selected component bit rates from a first leaf-range incoming bit rate Y1 (leaf). Preferably, the component bit rates for the pair are selected so that ratio of their values is maximally close to 1 (closer than ratio between values of other possible pairs).

2. combining the obtained bit rate Y1 (leaf) with another client being either an additional component bit rate Xi, or another similarly obtained Y2( leaf), and selecting an additional Cyclic Generator CG(branch) such that allows obtaining the two bit rates being combined, from a branch-range incoming bit rate Z1 (branch); Again, when seeking for this other client, its value is selected to be such to be maximally close to the value of the bit rate Y1 (leaf).

3. continuing combining the clients up to the moment when the last component bit rate is handled, and the incoming bit rate of the last CG is substantially equal to X1.

The system (tree) 80 is built from its leaves and comprises two leaf-range CGs 81 and 82. The CGs can be either low jitter ones, or not. Values n and m of CG 81 are selected so as to produce two outgoing bit rates being the two required component bit rates X2 and X4 from an incoming higher bit rate “Y1(leaf)”. The CG 82 is similarly selected so as to produce two component outgoing bit rates X3 and X5 from an incoming higher bit rate “Y2(leaf)”. The remaining intermediate CGs (a branch range CG 83 and a root-range CG 84 are shown in this example) are selected so as to ensure that the total given bit rate X1 is sufficient for the required bandwidths. If a spare bandwidth remains, it may be separated into one or more additional (or waste) bit rate(s). In this drawing, bit rate X6 is a-priori separated as being excessive (actually, representing a fictitious client). Therefore, X2, X3, X4 and X5 may be obtained respectively equal to the initial bit rates x2, x3, x4, x5 (shown in brackets near the corresponding component bit rates). Alternatively (if allowed/desired according to initial conditions of bandwidth allocation), one or more of the component bit rates X2, X3, X4, X5 may comprise waste bit rates, i.e., the spare bandwidth could be distributed there-between and form parts of the mentioned component bit rates X2, X3,X4, X5. It should be kept in mind that initial bit rates to be allocated are x2, x3 . . . , xN, wherein x2≦X2, x3≦X3 . . . , xN≦XN.

FIG. 6D illustrates another version of the binary tree constructing algorithm, where the system (tree) 90 of CGs (not mandatory the low jitter ones) is built starting from the root-range CG 91.

The CG 91 is selected so as to produce from the incoming high bit rate X1 two lower bit rates, one of which is a required component bit rate, say X2. The sum of the remaining component bit rates forms the second outgoing bit rate of the root CG 91.

A similar procedure is performed at each of the lower range CGs 92 and 93, up to obtaining all the required component bit rates. It goes without saying that a “waste” bit rate can also be organized, for example in the form of one of the component bit rates.

In the method of building the structure from the root, it is preferable that the component bit rate to be obtained at the root range is selected to be either essentially greater or essentially lower than other component bit rates.

The structure 90 could also be built from the leaf range upwards, based on the method described above with reference to FIG. 6C.

FIG. 6E illustrates a particular numerical example of dividing bit rates for bandwidth allocation, using the tree-like structure of CGs. Let the total bit rate 150 (say, Kbps) is to be divided so as to provide bandwidth allocation to the following initial bit rates x2, x3, x4, x5, x6: 2, 5, 17, 34 and 58 Kbps. The condition is to obtain low jitter in a total data flow formed from these further multiplexed corresponding data streams. The sum of the required intial bit rates is 116. It means that a bit rate 34 is a waste bit rate which can be either distributed between real clients during the bandwidth allocation, or separated into one or more separate fictitious “clients”. Let the selected tree-like structure is 100. The root joint 101 comprises a CG (not shown) that divides the total bit rate 150 (all bit rates are encircled) into a waste bit rate 34 and a really required sum of bit rates 116. Internal parameters m and n of the CG101 are selected to accomplish such a division. Further gradual division of the bit rates can be seen in the drawing. At the leaves range, the obtained component bit rates are respectively equal to the required initial bit rates x2, x3, x4, x5, x6. The figure, inter alia, also illustrates that the pairs of lower bit rates, combined at my range of the binary structure, are selected so that the bit rates values of the pair members be maximally close to one another ( ratio there-between is closer to 1 than ratio of “non-combined” bit rates). It has been noted by the Inventors, that such an approach allows obtaining the binary tree structure minimized from the point of jitter (for example, allowing low jitter bandwidth allocation and further low jitter multiplexing). One can see, that the structure 100 can be built either from the leaves, or from the root.

FIG. 7 illustrates a communication system 110 where a number of incoming data streams have initial bit rates x2, x3, . . . , xN. In this particular embodiment, the incoming data streams are mapped by enabling generators (EG) 111, 112, . . . 113 into respective higher bit rate component data streams (indicated by their bit rates as X2, X3, . . . , XN), for further multiplexing in a multiplexer 114 and transmitting over a communication path 115. Instead of the communication line 115, an external storage (such as RAM) can be utilized. For allocating bandwidths (bit rates) of the component data streams X2, X3, . . . , XN so that they could be further multiplexed into a common data stream not exceeding the total bit rate X1 allowed for the transmission path 115, the system 110 comprises a sub-system 116 for dividing the given total bit rate X1 into component bit rates X2, X3, . . . , XN. The system 1 16 (as well as the symmetric system 118 at the receiving side of the transmission path) is preferably built as a tree-like system of clock generators (CG), similar to those described and illustrated with reference to FIGS. 6A-6E. The bandwidth allocating system 116 supplies the obtained component bit rates in the from of clocks respectively marked as arrows X2, X3, . . . , XN outgoing the block 116, which can be used as respective high bit rates (clocks) in the enable generators 111-113. In this particular embodiment, the component bit rates X2, X3, . . . , XN are respectively greater than the initial bit rates x2, x3, . . . , xN, and each of the initial bit rates x(i) is therefore mapped into the corresponding component bit rate, marked X(i). Preferably, the asynchronous type of mapping is utilized at the generators 111-113 and their respective ones 121-123 at the receiving side of the system (please refer to FIG. 3). It should be noted, that if any allocated Xi=xi, no mapping is required and no cyclic generators are needed for this particular i-th data stream. To perform low jitter multiplexing of the component data streams (marked as arrows X2, X3, . . . , XN incoming the multiplexer 114), the tree-like structure 116 should preferably be a low jitter one, and the clock pattern of the obtained component bit rates should be taken into account in the multiplexer 114. In this example, the mentioned clock pattern reflects status of the binary tree-like structure in block 116. Periodically, information concerning the status of block 116 and the status of mapping (enable) generators- if any- is communicated from the transmitted site to the receiving site. Status of the binary structure 116 actually comprises a set of statuses of all cyclic generators CG of the structure, each particular status including internal state S of the CG and, preferably, update of current values of m and n thereof. Status ofian enable generator also comprises its internal state S and information about its m and n parameters. The way of communication can be via a management system (symbolically shown by a dotted line between blocks 116 and 118), but preferably via data frames transmitted over the communication line 115. Such a periodic data frame, one of which (120) is shown in the drawing in a most symbolic way, may comprise both the information about status of the binary tree (S₁₁₆) for allocating component data streams at the remote site, and the information about status of each of the enable generators 111, 112, . . . , 113 (S, m, n thereof) for detecting the mapped “netto” information in the respective component data streams. In practice, information bits belonging to status of different CGs and EGs are usually distributed and mixed in a frame of the common data stream, due to the principle of low jitter multiplexing. Based on the communicated status information, blocks 116 and 118 can operate in accord. In this example, the information concerning status (S₁₁₆) of the binary tree 116 is received by the binary tree 118 at least once, used by it for updating its own state and thus for ensuring suitable de-multiplexing of the received data stream at a DMUX 119. For the purpose of further de-mapping the component data streams obtained upon de-multiplexing, statuses of the Enable Generators 111, 112 . . . 113 are extracted from these component data streams and utilized by respective Enable Generators 121, 122 . . . 123.

The system of FIG. 7 illustrates an exemplary implementation of a combined method where the method of bandwidth allocation (using the binary tree-like structure of Cyclic Generators CG) is integrated with the method of low jitter multiplexing using the same structure, and further with the method of mapping a data stream onto a higher bit rate data stream (in this case having the “allocated” bit rate), the last method being performed with the aid of the inventive Cyclic Generator CG. Other embodiments may implement different combined methods and may comprise restricted combinations of elements—the block 116(118) and the MUX 114(DMUX119) for bandwidth allocation with further multiplexing-de-multiplexing, the block 116(118) and at least one mapping EG(de-mappingEG) for bandwidth allocation and mapping/de-mapping, etc.

It should be appreciated that, in the frame of the inventive concept, other implementations of the cyclic (enabling) generator and a tree-like binary structure can be found, various modifications of the mapping-de-mapping technique and methods of bandwidth allocation and low jitter multiplexing can be suggested, as well as other implementations of a chip utilizing a common internal clock can be proposed, which should all be considered parts of the invention.

1. A binary tree-like structure for converting bit rates in a telecommunication system and comprising at least one cyclic generator (CG),
wherein each particular CG is adapted to present a higher bit rate called R1 substantially as a sum of two lower bit rates called R2 and R3 by cyclically producing, per n clocks of the bit rate R1, m first type signals as clocks of the bit rate R2 and (n−m) second type signals as clocks of the bit rate R3, where m and n are parameters of said CG and integers, m<n;
so that said two lower bit rates R2 and R3 are presented as follows, based on its parameters m and n: R2=mR1/n, R3=(n−m)R1/n;
and wherein the higher bit rate R1 of a particular CG is either obtained from outside of said structure or constitutes a lower bit rate of another, upper range CG of the structure, while each of the lower bit rates R2 or R3 of a particular CG is either dispatched away from the structure or constitutes a higher bit rate of another, lower range CG of the structure.

2. The binary tree-like structure according to claim 1, for bandwidth allocation in a telecommunication system, the structure being capable of allocating component bit rates by dividing a given total bit rate called X1 into two or more component bit rates called X2, . . . , XN being respectively equal or more than required bit rates called x1, . . . , xN, so that the total bit rate is equal to the sum of component bit rates (X1=X2+ . . . XN ≧x2+ . . . +xN),
said structure dividing the total bit rate X1 into a plurality of component bit rates X2, . . . , XN according to a binary tree algorithm, so that said total bit rate X1 is fed to one CG of the structure as the higher bit rate of said CG, and each of the component bit rates X2, . . . , XN is received as a lower bit rate of either of said CG or another CG of the structure,
wherein each of the Cyclic Generators divides its higher bit rate R1 into its two lower bit rates R2 and R3, based on its parameters m and n as follows:
R2=mR1/n, R3=(n−m)R1/n.

3. A cyclic generator (CG) for converting bit rates, capable of generating first type signals and second type signals, the generator being adapted to present a higher bit rate R1 substantially as a sum of two lower bit rates R2 and R3,
wherein:
R1=R2+R3,
R2=mR1/n, R3=(n−m)R1<n.
m and n are integers and parameters of said generator, and
wherein:
the CG is capable of generating m of said first type signals and (m−n) of said second type signals per n clocks of the bit rate R1, while substantially uniformly distributing said m signals among said (n−m) signals,
said m signals serving as m clocks of the bit rate R2, while said (n−m) signals serving as (n−m) clocks of the bit rate R3.

4. The generator CG according to claim 3, having a number of changeable internal states, being not greater than n, and capable of generating first type/second type signals according to the following rules:
a) selecting an initial state S of the generator, being an integer S≦n;
b) at a clock of bit rate R1, obtaining a current state of the generator S′=S+m;
c) if S′≧n, generating a first type signal, and replacing the current state S′with (S′−n);
if S′<n, generating a second type signal, without changing the current state S′,
d) at the next clock of the bit rate R1, repeating from step b, while using the current state as a new initial state.

5. The generator CG according to claim 3, being a generator of enabling/disabling signals (EG), wherein the first type signals are enable signals while the second type signals are disable signals.

6. A method of low jitter mapping, of a data stream having a lower bit rate called C, into a data stream having a higher bit rate called H, and using stuffing signals with a bit rate called ST, by utilizing the Cyclic Generator (CG) according to claim 3, and by representing the bit rate R1 of the CG by the bit rate H, the bit rate R2 of the CG by the bit rate C, and the bit rate R3 of the CG by the bit rate ST,
the method ensuring that, statically or dynamically, actual values R1ₜ, R2ₜ, R3ₜof the respective bit rates R1, R2, R3 of the CG are bound substantially as follows:
R1ₜ=R2ₜ+R3ₜ,
by fulfilling one of the following conditions:
a) ensuring C/H=const;
b) dynamically adjusting a ratio m/n of the CG to (m/n)ₜ if C/H≠const.

7. The method according to claim 6 for low-jitter mapping of an incoming data stream having the bit rate C, into a succession of data frames of an outgoing data stream having the higher bit rate H, wherein each of the frames comprises an overhead portion and a payload portion, the method comprises:
using a first said CG to control filling the payload portion of each data frame of the outgoing data stream with information bits of the incoming data stream diluted with stuffing bits, wherein the filling is performed at the bit rate H, the incoming data stream has the bit rate C, the stuffing bits have the bit rate ST;
using at least one predetermined location in the overhead portion of at least one of said data frames to indicate an internal state of the EG corresponding to a suitable payload portion, for further de-mapping of said portion.

8. The method of low-jitter mapping according to claim 7, followed by a step of de-mapping at a receiving end with the aid of a second CG identical to the first CG, wherein the de-mapping step comprises:
adjusting the second CG to have parameters m and n respectively identical to said parameters of the first CG,
obtaining the internal state of the first CG from said predetermined location of the overhead portion of one of said frames and setting the second CG into the obtained internal state,
using the second CG to read the incoming data stream, from the payload portion corresponding to the internal state.

9. The method according to claim 7, serving either for synchronous or asynchronous mapping, wherein the synchronous mapping is performed if the parameters m and n are respectively constant and known in advance, and the asynchronous mapping is performed when the ratio m/n≠const, and comprises:
monitoring ratio between the bit rates H and C, periodically adjusting the ratio m/n to (m/n)ₜ, and, for further de-mapping, simultaneously indicating in a predetermined location of the overhead portions of the data frames, information enabling obtaining the adjusted ratio (m/n)ₜ actual for a particular period of transmission.

10. A method for transporting, with a low jitter, “k” incoming data streams having arbitrary bit rates, by “k” SONET/SDH lower order data streams further multiplexed into a SONET/SDH higher order data stream, the method comprising
mapping each of said incoming data streams into a corresponding lower order SDH/SONET data stream according to claim 6, and
multiplexing the obtained “k” lower order SONET/SDH data streams into the higher order transport data stream using a bit-interleaving principle.

11. A system for low jitter mapping of an incoming data stream having a lower bit rate, into a succession of data frames of an outgoing data stream having a higher bit rate, capable of performing the method according to claim 6.

12. A system for low jitter data transmission, capable of performing the method according to claim 10.

13. A system for handling a number of incoming data streams with respective different bit rates called R2a, R2i, . . . , R2k at its inputs, the system outputting one or more outgoing data streams at its outputs, respectively having the same bit rates R2a, R2i. . . R2k or bit rates derived therefrom, by utilizing inside the system one common internal bit rate called R1; the system being characterized in that it comprises, at least at its inputs, a number of CG for respectively converting said incoming data streams to the internal bit rate R1, each of said CG being designed according to claim 3.

14. The system according to claim 13, wherein each of said CG (CGi) placed at its inputs is operative to cooperate with an input FIFO (FIFOi) adapted to store data inputted at the bit rate R2i, while the corresponding CGi is capable of creating enabling/disabling signals to form a pair (i) of internal streams by:
a) reading the FIFOi at the bit rate R1 thus creating an internal data stream having the bit rate R1, and
b) transmitting an internal stream of the enabling/disabling signals in parallel with the internal data stream;
the system being also characterized in that, at least one of said pairs of internal streams, upon being handled in the system, is finally utilized at a corresponding output for creating the corresponding outgoing data stream at the bit rate R2i or a bit rate derived there-from.

15. The binary structure according to claim 1, wherein said at least one Cyclic Generator is the CG according to claim 3, thereby capable of performing bandwidth allocation suitable for low jitter multiplexing.

16. The binary tree-like structure according to claim 2, wherein one or more of said component bit rates X2, . . . , XN at least partially comprises waste bit rate.

17. The binary tree-like structure according to claim 2, arranged so that majority of CG are built so that a particular CG of the majority presents its higher bit rate R1 as a sum of its two lower bit rates R2 and R3, wherein a ratio R2/R3 of said CG is closer to 1, than a ratio between any of the R2 and R3 and a lower bit rate of another CG of the structure.

18. A method of bandwidth allocation in a communication network by utilizing a binary tree-like structure according to claim 1, for dividing a given total bit rate X1 into two or more component bit rates X2, . . . , XN being respectively equal or more than required bit rates x2, . . . xN of two or more initial data streams.

19. The method according to claim 18, further comprising multiplexing the two or more initial data streams that have respectively obtained the allocated component bit rates X2, . . . , XN, under supervision of said binary tree-like structure, by producing from said structure periodically distributed clocks assigned to different component bit rates, the method further comprises providing information on status of said binary tree-like structure for further demultiplexing said two or more initial data streams.

20. The method according to claim 19, further comprising periodically transmitting the information on status of said binary tree-like structure placed at a transmitting site to an equivalent binary tree-like structure placed at a receiving site, and de-multiplexing the multiplexed said two or more initial data streams under control of the binary tree-like structure placed at the receiving site and by using said information.

21. The method according to claim 18, comprising mapping of at least one of said initial data streams upon allocating for them the respective component bit rates X2, . . . , XN, the mapping of a particular initial data stream being performed by providing an additional cyclic generator CG and utilizing it according to the method of claim 6, wherein the higher bit rate R1 of the additional CG is represented by a component bit rate X(i) allocated for said particular data stream, and the lower bit rate R2 of the additional CG is represented by the required bit rate x(i) of said particular data stream.

22. A telecommunication system comprising a first assembly including a first binary tree-like structure for bandwidth allocation according to claim 2, and a multiplexer associated with the first binary tree-like structure the first assembly being capable of judiciously dividing a given total bit rate between a number of initial data streams, correspondingly multiplexing said initial data streams, and producing information about status of the first binary tree-like structure.

23. The telecommunication system according to claim 22 further comprising a second assembly comprising a demultiplexer associated with a second binary tree-like structure equivalent to said first structure, said first assembly being in communication with said second assembly for transmitting data and information about status of the first binary tree-like structure; the second assembly, using said information, being capable of de-multiplexing the initial data streams upon being multiplexed by said first assembly.

24. A telecommunication system comprising a binary tree-like structure for bandwidth allocation according to claim 2, further comprising at least one additional cyclic generator CG according to claim 3 for mapping at least one of said initial data streams, said at least one additional CG being associated with said binary three-like structure so that one of the component bit rates X2, . . . , XN obtained in the structure is used as the higher bit rate RI of the additional CG, and a corresponding one of the required bit rates x2, . . . , xN is used as a lower bit rate R2 of the additional CG, the system thereby enabling conversion of at least one lower required bit rate into a higher allocated component bit rate.
